(19) United States
(12) Patent Application Publication
(10) Pub. No.: US 2009/0035534 A1
(43) Pub. Date: Feb. 5, 2009

(54) Method and structure of a reusable substrate

(75) Inventors: Juh-Yuh Su, Tainan County (TW); Hung-Jen Chen, Tainan City (TW)

Correspondence Address: BACON & THOMAS, PLLC, 625 SLATERS LANE, FOURTH FLOOR, ALEXANDRIA, VA, 22314-1176, US

(73) Assignees: JUH-YUH SU, Tainan County (TW); HUNG-JEN CHEN, Tainan City (TW)

(21) Appl. No.: 12/155,870

(22) Filed: Jun. 11, 2008

(30) Foreign Application Priority Data
Jul. 30, 2007 (TW) 096127855

(51) Int. Cl. H01L 21/311; B32B 5/00

(52) U.S. Cl. 428/195.1; 438/700; 257/E21.249

(57) ABSTRACT

A reusable substrate structure and a method of handling the reusable substrate are disclosed. The reusable substrate structure comprises a substrate, at least one epitaxial layer and at least one inter layer. The method used in this invention is by employing a separating method in order to decompose the inter layer. Since the inter layer is decomposed, the substrate and the epitaxial layer will be separated. This achieves the goal of reusable substrate and then can save the material cost without additional wasting.

### FIELD OF THE INVENTION

The present invention generally relates to a reusable substrate structure, and a method to handle the reusable substrate. More particularly, it relates to the field of applying separating method in the inter layer in order to separate a substrate and an epitaxial layer, and then to achieve the goal of reusable substrate.

### BACKGROUND OF THE INVENTION

As is known in the art, the semiconductor manufacturing method is the process used to create the integrated circuits (IC) on the wafer. The processes contain several steps, included the photo-lithography, etching, physical vapor deposition (PVD) or chemical vapor deposition (CVD), polishing, ion-implanting and . . . etc. Generally, photo-lithography is the process used for transferring the geometric pattern onto the wafer. The physical vapor deposition (PVD) or chemical vapor deposition (CVD) is the process that used for adding another material onto the wafer. The etching process is used for removal material from the wafer.

Overall, the semiconductor manufacturing method is the one combined with some of above in order to produce semiconductor devices. Since the devices have been completed, it will go on to the dicing step in order to do future assembly and testing.

In recently years, the micro electromechanical (MEMS) technology, which refers to a process whereby micron-sized mechanical devices are fabricated on silicon wafers, has been developed after the semiconductor manufacturing methods. The micron-sized mechanical devices are included the optoelectronic components, sensor components and other micron-sized devices.

However, there are still some difficulties are associated with fabricating a MEMS device. One of them is the entire substrate volume in a MEMS device, which is generally up to 80% or more. Therefore, a chemical mechanical polishing (CMP) are normally applied to polish the substrate in order to reduce the substrate thickness. This sometimes results in the substrate surface damage or debris. In this case, the substrate may hard to resist any chemical or physical impact and can not be used again.

Another difficulty associated with fabricating a MEMS device is the high material cost. For example, the higher proportion cost for a light-emitting diode (LED) production is in its material cost, included the substrate, organic metals, special gases, epoxy resin and fluorescent powder, whereby the substrate used as function load here. To be more specific in the selected substrate type of optoelectronic field, the most popular used substrates are GaAs substrates, GaP substrates, sapphire substrates and Silicon carbide (SiC) substrates. The GaP substrates were used by the GaP, GaAsP binary or ternary light-emitting diodes (LED) or other optoelectronic components. The GaAs substrates were mainly used by AlGaAs, GaAsP, AlGaInP ternary or quaternary light-emitting diodes or optoelectronic components. The sapphire substrate and SiC substrates were mainly used in indium gallium nitride light-emitting diodes (LED) or photoelectric components.

In generally, most of the substrate manufacturers have their attention on the type of substrate they are going to use, because the brightness, efficiency, and the life cycle time of the light-emitting devices were normally based on the choice of the substrate. The sapphire substrate is more general used in the GaN light-emitting diodes (LED) in production. The reason without choosing SiC substrate is because of its high price.

However, the material prices for most substrates are still very high comparing to other costs. Therefore, the way to invent a reusable substrate can provide a method to lower down the cost and the application field for others can be then more extensive.

The inventor of the present invention based on years of experience on related research and development of the optoelectronic component industry to invent a reusable substrate structure and a method of handling the reusable substrate.

### SUMMARY OF THE INVENTION

The object of the present invention is to provide a reusable substrate structure and a method of handing the reusable substrate in order to provide way of reusable substrate operation and then give advantage of lowering the cost of material down.

According to the objective of the present invention, a reusable substrate structure has been presented, comprising a substrate; at least one epitaxial layer disposed over the substrate, wherein the epitaxial layer has at least one pattern on it; and at least one inter layer existed between the substrate and the epitaxial layer, wherein the inter layer was applied a separating methods to separate said substrate and said epitaxial layer.

Furthermore, a method for handling the reusable substrate has also been presented which comprises: providing a substrate; forming an inter layer over said substrate; forming at least one epitaxial layer, wherein the epitaxial layer is fabricated at least one pattern; applying one cutting method to form at least one recess through said epitaxial layer to expose said inter layer, wherein the cutting is implemented along with the two different said pattern space; applying a one carrier to protect said pattern and provide stability and strength to the pattern function; and finally, applying an etchant, where the inter layer is decomposed by the etchant where starts from the contact areas between said recess and said inter layer.

### BRIEF DESCRIPTION OF THE DRAWINGS

FIG. 1 is a cross-sectional drawing of a reusable substrate structure;

FIG. 2 is a cross-sectional drawing of the first example of a reusable substrate structure;

FIG. 3 is a cross-sectional drawing of the second example of a reusable substrate structure;

FIG. 4 is a cross-sectional drawing of the third example of a reusable substrate structure; and

FIG. 5 shows a flow chart of the manufacturing process of the reusable substrate structure according to a preferred embodiment of the present invention.

### DETAILED DESCRIPTION OF THE PREFERRED EMBODIMENTS

To make it easier for our examiner to understand the objective of the invention, its innovative features and performance, a detailed description and technical characteristics of the present invention are described together with the drawings as following.

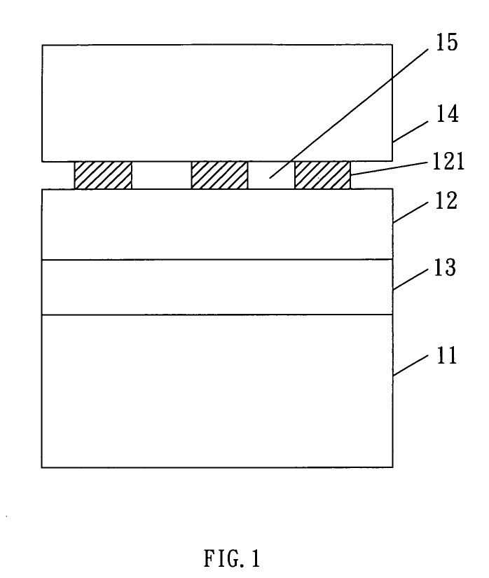

Referring to FIG. 1, a cross-sectional drawing of a reusable substrate structure is illustrated. The reusable substrate structure comprises a substrate 11, at least one epitaxial layer 12, and at least one inter layer 13. As is known in the art, the inter layer 13 can be fabricated over the substrate 11 by the Chemical vapor deposition (CVD) or physical vapor deposition (PVD). The epitaxial layer 12 over the substrate 11 is fabricated at least one pattern 121, by the well-know technology of photolithography and etching process. Therefore, the inter layer 13 is formed between the substrate 11 and the epitaxial layer 12. The material of inter layer 13 or the composition of inter layer 13 is different from the substrate 11 and the epitaxial layer 12 that the inter layer 13 can work as a separation interface. The carrier 14 mounts above the pattern 121, where the pattern 121 are on the epitaxial layer 12. The carrier 14 can work as a protection to the pattern 121 and provide stability and strength to the pattern 121 function. The separating method 15 can provide ways to decompose the inter layer 13 in order to separate the substrate 11 and the epitaxial layer 12, where the material of inter layer 13 is different from the substrate 11 and the epitaxial layer 12.

The material of substrate 11 is one from varies of substrate type, included the sapphire substrate, GaAs substrate, SiC substrate, GaP substrate, ZnO substrate, InP substrate or Silicon Substrate. The pattern is formed for Integrated Circuit (IC). The epitaxial layer 12 contains at least one elements form the periodic table of group IIA, IIB, IIIA, IVA, VA and VIA, such as GaInP. The inter layer 13 comprise at least one group selected from Al(x)Ga(y)In(z)P, Al(x)Ga(y)As(z)P(v), Al(x)Ga(y)In(z)N, Al(x)Ga(y)In(z)Sb or Si(x)Ge(y)C(z). The group of Al(x)Ga(y)As is the most important in three elements alloy semiconductor because its lattice constant is small different from GaAs, therefore the Al(x)Ga(y)As can fabricate appropriately over the GaAs substrate. The carrier 14 can be polysilicon, glass, quartz, polymer, metal or any combination of the above mention carrier materials.

The substrate 11 can comprise at least one layer of epitaxial. The separating method 15 can be one by etchant or one by reacted light. The reacted light can be a laser to give the sufficient energy to decompose the inter layer 13. Or, the etchant can react with the inter layer 13, and decompose the inter layer 13. The etchant can be in a form of liquid or gas. Consequently, since the inter layer 13 is decomposed, the substrate 11 and the epitaxial layer 12 are separated.

The carrier 14 has the character of penetration that the etchant can penetrate the carrier 14 to reach the inter layer 13, and then decompose the inter layer 13. As mention before that the material of a substrate 11 is different from the inter layer 13, the reaction between the substrate 11 and the etchant is near to the ground, so that the substrate can be kept afterward.

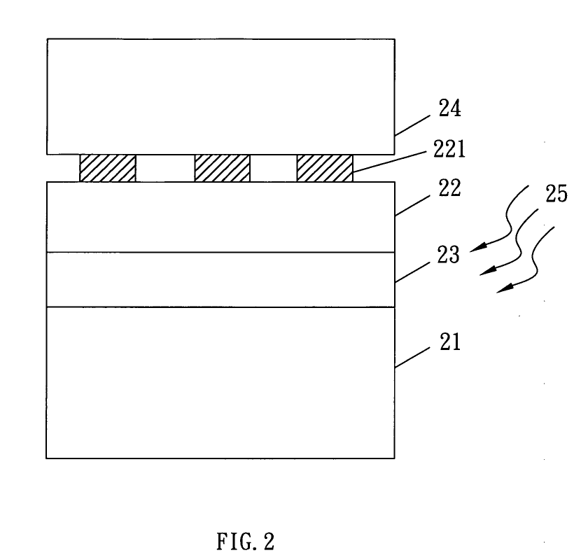

Referring to FIG. 2, it illustrates a cross-sectional drawing of the first example of a reusable substrate structure. In the preferred embodiment, the first example of a reusable substrate structure comprises a substrate 21, at least one epitaxial layer 22, a inter layer 23, a carrier 24 and a laser 25. As is known in the art, the inter layer 23 can be fabricated over the substrate 21 by the Chemical vapor deposition (CVD) or physical vapor deposition (PVD). The epitaxial layer 22 over the substrate 21 is fabricated at least one pattern 221, by the well-know technology of photolithography and etching process. Therefore, the inter layer 23 is formed between the substrate 21 and the epitaxial layer 22. The material of inter layer 13 is different from the substrate 21 and the epitaxial layer 22 that the inter layer 23 can work as a separation interface. The carrier 24 can work as a protection to the pattern 221 and provide stability and strength to the pattern 221 function. The separating method 25 can provide ways to decompose the inter layer 23 in order to separate the substrate 21 and the epitaxial layer 22, where the material of inter layer 23 is different from the substrate 21 and the epitaxial layer 22. The laser 25 can provide the sufficient energy to break off the binding energy of the inter layer 23. Consequently, since the inter layer 23 is decomposed, the substrate 21 and the epitaxial layer 22 are separated.

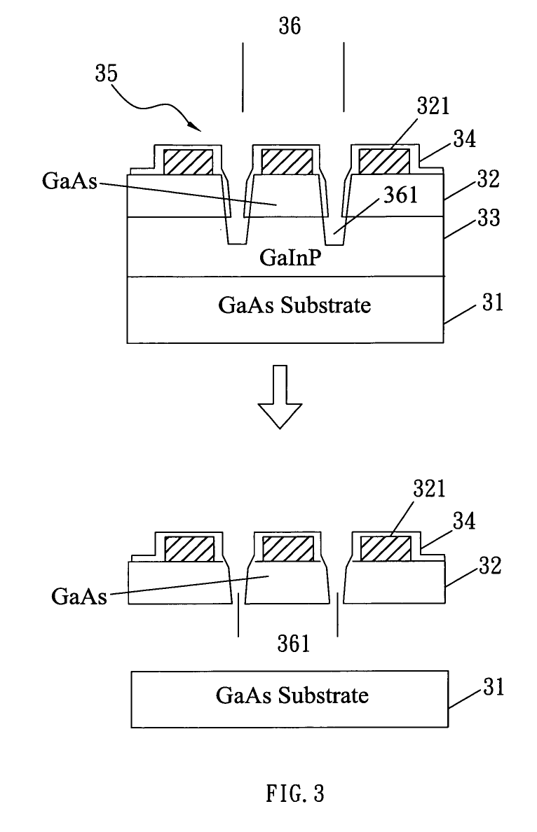

Referring to FIG. 3, it illustrates a cross-sectional drawing of the second example of a reusable substrate structure, according to an embodiment of the present invention. In the preferred embodiment, the second example of a reusable substrate structure comprises a GaAs substrate 31, at least one GaAs epitaxial layer 32, at least one GaInP inter layer 33, a protection layer 34, an etchant 35 and at least one cutting method 36. As is known in the art, the GaInP inter layer 33 can be fabricated over the GaAs substrate 31 by the Chemical vapor deposition (CVD) or physical vapor deposition (PVD). The GaAs epitaxial layer 32 over the GaAs substrate 31 is fabricated at least one pattern 321, by the well-know technology of photolithography and etching process. Therefore, the GaInP inter layer 33 is formed between the GaAs substrate 31 and the GaAs epitaxial layer 32. The material of GaInP inter layer 33 is different from the GaAs substrate 31 and the GaAs epitaxial layer 32 that the GaInP inter layer 33 can work as a separation interface.

A cutting method 36, such as by diamond saw blade, laser, or etchant, is applied to form at least one recess 361 through GaAs epitaxial layer 32 to expose the GaInP inter layer 33. Here, the recess 361 can be 100% through the GaInP inter layer 33 or less than 100%. The cutting is implemented along within the space between one of the pattern 321 and another pattern 321. The protection layer 34 is needed when the etchant 35 impacts the pattern 321 or there is a reaction happened between the GaAs epitaxial layer 32 and the etchant 35. On the other hand, the protection layer 34 does not have to apply when GaAs epitaxial layer 32 and the etchant 35 have no reaction.

An etchant 35 is applied in order to decompose GaInP inter layer 33. The decomposition starts from the contact areas between the recess 361 and the GaInP inter layer 33. During the decomposition process, the GaAs substrate 31 can still keep remain without destruction because the impact from the etchant 35 (such as: HCl) is limited. Consequently, since GaInP inter layer 33 is decomposed, the GaAs substrate 31 and the GaAs epitaxial layer 32 are separated. Here, the etchant 35 takes HCl as an example because the HCl can decompose the GaInP inter layer 33.

A carrier, such as polysilicon, glass, polymer, or quartz, can be mounted on the GaAs epitaxial layer 32 or on the protection layer 34 to work as a protection to the pattern 321 and provide stability and strength to the pattern 321 function. The carrier is made by the small pore materials or the high porosity materials. The high porosity materials have the high penetrability that can give more contact area between the etchant 35 and the GaInP inter layer 33, so that the etching speed can be increased. The small pore materials can be added one diversion hole or diversion channel on the carrier in order to increase the contact area between the etchant 35 and the GaInP inter layer 33.

The etchant 35 can be in a form of liquid or gas. The etchant 35 can be acid etchant or alkaline etchant. The acid etchant is selected from the group consisting of: sulfuric acid (H₂SO₄), hydrochloric acid (HCl), Hydrofluoric acid (HF), Hydrogen cyanide (HCN), nitric acid (HNO₃), Acetic acid (CH₃COOH), and Phosphoric acid (H₃PO₄). The alkaline etchant is selected from the group consisting of: ammonium hydroxide (NH₄OH), Potassium Hydroxide (KOH), Sodium hydroxide (NaOH), Calcium hydroxide (Ca(OH)₂), and Barium hydroxide (Ba(OH)₂). The gas etchant is selected from the group consisting atom of fluorine, chlorine, bromine, iodine, and sulfur.

The hydrochloric acid (HCl) has the chemical reaction with the GaInP and the Ammonium hydroxide (NH₄OH) has the chemical reaction with the GaAs.

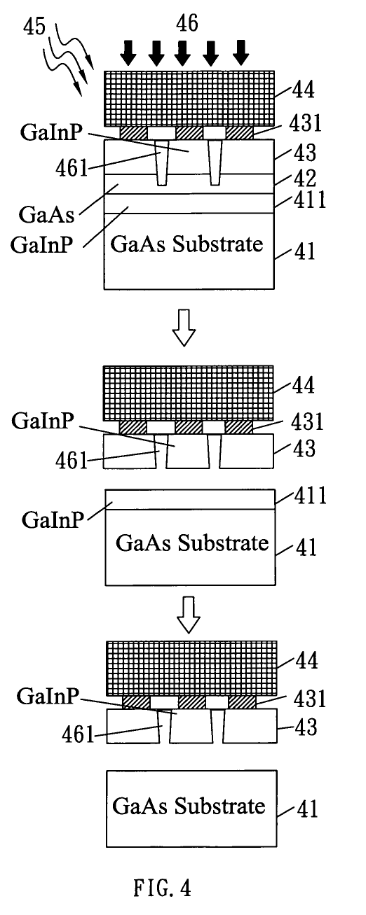

Referring to FIG. 4, it illustrates a cross-sectional drawing of the third example of a reusable substrate structure, according to an embodiment of the present invention. In the preferred embodiment, the third example of a reusable substrate structure comprises a GaAs substrate 41, a GaAs inter layer 42, a first GaInP epitaxial layer 43, a carrier 44, an etchant 45 and a laser 46. The GaAs substrate 41 contains at least one layer of secondary GaInP epitaxial layer 411. The GaAs inter layer 42 is deposited over the secondary GaInP epitaxial layer 411. The first GaInP epitaxial layer 43 is over the GaAs inter layer 42. The GaAs inter layer 42 is formed between the GaAs substrate 41 and the first GaInPs epitaxial layer 43, where the material of GaAs inter layer 42 is different from the first GaInP epitaxial layer 43 and the secondary GaInP epitaxial layer 411, that the GaAs inter layer 42 can work as a separation interface.

The first GaInP epitaxial layer 43 can be fabricated at least one pattern 431 on it. A laser 46 is applied to form at least one recess 461 through the first GaInP epitaxial layer 43 to expose the GaAs inter layer 42. Here, the recess 461 can be 100% through the GaAs inter layer 42 or less than 100%. The cutting is implemented along within the space between one of the pattern 431 and another pattern 431. The carrier 44 is a high porosity material and the impact from the etchant 45 to the carrier 44 is limited, therefore, the high porosity material can increase the penetrability between the etchant 45 (such as, NH₄OH) and the GaAs inter layer 42 that increased the etching speeds. The carrier 44 may applied on the first GaInP epitaxial layer 43 in the situations when the protection of the first GaInP epitaxial layer 43 are needed.

The etchant 45 (such as, NH₄OH) can penetrate through the carrier 44 to reach the recess 461 to decompose the GaAs inter layer 42. After the GaAs inter layer 42 has been decomposed by etchant 45, the second GaInP epitaxial layer 411 separate from the first GaInP epitaxial layer 43. Besides, the second GaInP epitaxial layer 411 can be etched by the acid etchant (HCl) so as the second GaInP epitaxial layer 411 can be separated from the first GaAs substrate. Here, the etchant 45 take NaOH as an example because the alkaline etchant 45 can decompose the GaAs. Additionally, the GaAs substrate 41 can contain more layer of epitaxial layer. Here, the second GaInP epitaxial layer 411 is only as an example.

If the first GaInP epitaxial layer 43 reacts with the etchant 45, a protection layer (such as, photo resist) can be applied on the first GaInP epitaxial layer 43 and pattern 431 in order to avoid the damage from the etchant 45, that can increase the stability and strength to the pattern 431 function.

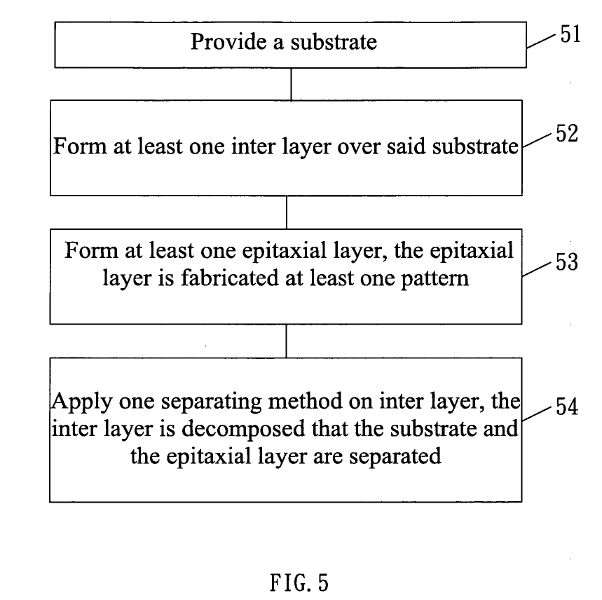

Referring to FIG. 5, it is a flow chart of the manufacturing process of the reusable substrate structure according to a preferred embodiment of the present invention. The method for handling the reusable substrate, comprising:

Step 1: providing a substrate;

Step 2: forming at least one inter layer over said substrate;

Step 3: forming at least one epitaxial layer, the epitaxial layer is fabricated at least one pattern;

Step 4: applying one separating method on inter layer, the inter layer is decomposed so that the substrate and the epitaxial layer are separated.

After above working steps, the substrate keep remains and the epitaxial layer can still work for future device manufacturing. That achieves the goal of a reusable substrate and the cost can be therefore lowered down.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

In summation of the description above, the present invention is novel and useful and definite enhances the performance over the conventional structure and further complies with the patent application requirements and is submitted to the Patent and Trademark Office for review and granting of the commensurate patent rights

What is claimed is:

1. A reusable substrate structure, comprising:
a substrate;
at least one epitaxial layer over the substrate, wherein said epitaxial layer has at least one pattern on it; and
at least one inter layer existed between said substrate and said epitaxial layer, wherein said inter layer was applied a separating method to separate said substrate and said epitaxial layer.

2. The reusable substrate structure of claim 1, wherein said separating method is an etchant or a reacted light.

3. The reusable substrate structure of claim 2, wherein said reacted light is laser.

4. The reusable substrate structure of claim 2, wherein said reacted light has the sufficient energy to decompose said inter layer.

5. The reusable substrate structure of claim 2, wherein said etchant is acid etchant or alkaline etchant.

6. The reusable substrate structure of claim 2, wherein said etchant is in the form of liquid or gas.

7. The reusable substrate structure of claim 1, wherein said substrate comprises at least one of epitaxial layer.

8. The reusable substrate structure of claim 1, wherein said inter layer has the substantially different material or different composition than said substrate and said epitaxial layer.

9. The reusable substrate structure of claim 5, wherein said acid etchant is selected from the group consisting of sulfuric acid (H₂SO4), hydrochloric acid (HCl) Hydrofluoric acid (HF), Hydrogen cyanide (HCN), nitric acid (HNO₃), Acetic acid (CH₃COOH), and Phosphoric acid (H₃PO₄).

10. The reusable substrate structure of claim 5, wherein said alkaline etchant is selected from the group consisting of ammonium hydroxide (NH₄OH) Potassium Hydroxide (KOH), Sodium hydroxide (NaOH), Calcium hydroxide (Ca(OH)₂), and Barium hydroxide (Ba(OH)₂).

11. The reusable substrate structure of claim 9, wherein said hydrochloric acid (HCl) has the chemical reaction with the AlGaInP.

12. The reusable substrate structure of claim 10, wherein said Ammonium hydroxide (NH4OH) has the chemical reaction with the GaAs.

13. The reusable substrate structure of claim 1, wherein said substrate is selected from the group consisting of sapphire substrate, GaAs substrate, SiC substrate GaP substrate, ZnO substrate, InP substrate or Silicon Substrate.

14. The reusable substrate structure of claim 1, wherein said pattern is formed for Integrated Circuit (IC).

15. The reusable substrate structure of claim 1, wherein said epitaxial layer comprises at least one elements form the periodic table of group □A, □B, □A, □A, □A and □A.

16. The reusable substrate structure of claim 1, wherein said inter layer comprise at least one group selected from Al(x)Ga(y)In(z)P, Al(x)Ga(y)As(z)P(v), Al(x)Ga(y)In(z)N, Al(x)Ga(y)In(z)Sb or Si(x)Ge(y)C(z).

17. A method for handling the reusable substrate, comprising:
providing a substrate;
forming at least one inter layer over said substrate;
forming at least one epitaxial layer, the epitaxial layer is fabricated at least one pattern;
applying one cutting method to form at least one recess through said epitaxial layer to expose said inter layer, the cutting is implemented along within the space between one of the pattern and another pattern;
applying an etchant, said inter layer is decomposed by said etchant that starts from the contact areas between said recess and said inter layer.

18. The reusable substrate structure of claim 17, wherein said cutting is applied by diamond saw blade, laser, or etchant.

19. The reusable substrate structure of claim 17, wherein said recess is 100% through said inter layer or less than 100%.

20. A method for handling the reusable substrate, comprising:
providing a substrate;
forming at least one inter layer over said substrate;
forming at least one epitaxial layer, the epitaxial layer is fabricated at least one pattern;
applying one cutting method to form at least one recess through said epitaxial layer to expose said inter layer, the cutting is implemented along within the space between one of the pattern and another pattern;
applying at least one carrier, the carrier protects said pattern and provide stability and strength to the pattern function;
applying an etchant, said inter layer is decomposed by said etchant that starts from the contact areas between said recess and said inter layer.

21. The reusable substrate structure of claim 20, wherein said recess is 100% through said inter layer or less than 100%.

22. The reusable substrate structure of claim 20, wherein said carrier is made by the small pore materials or the high porosity materials.

23. The reusable substrate structure of claim 22, wherein said high porosity materials are hard to react with said etchant. The high porosity materials have the high penetrability and then can provide more contact area between the said etchant and said inter layer in order to increase the etching speed.

24. The reusable substrate structure of claim 22, wherein said small pore materials can be added one diversion hole or diversion channel on said carrier to increase the contact area between the said etchant and said inter layer.

25. A method for handling the reusable substrate, comprising:
providing a substrate;
forming at least one inter layer over said substrate;
forming at least one epitaxial layer, the epitaxial layer is fabricated at least one pattern;
applying one separating method on inter layer, the inter layer is decomposed so that the substrate and the epitaxial layer are separated.
